(19) United States
(12) Patent Application Publication
(10) Pub. No.: US 2013/0015518 A1
(43) Pub. Date: Jan. 17, 2013

(54) SEMICONDUCTOR MEMORY DEVICE

(71) Applicants: Hiroyasu SATO, Kanagawa-ken (JP); Kiyohito NISHIHARA, Kanagawa-ken (JP); Hidefumi NAWATA, Kanagawa-ken (JP); Masayuki ICHIGE, Kanagawa-ken (JP); Ryuji OHBA, Kanagawa-ken (JP)

(72) Inventors: Hiroyasu SATO, Kanagawa-ken (JP); Kiyohito NISHIHARA, Kanagawa-ken (JP); Hidefumi NAWATA, Kanagawa-ken (JP); Masayuki ICHIGE, Kanagawa-ken (JP); Ryuji OHBA, Kanagawa-ken (JP)

(73) Assignee: Kabushiki Kaisha Toshiba, Tokyo (JP)

(21) Appl. No.: 13/353,818

(22) Filed: Jan. 19, 2012

(30) Foreign Application Priority Data
Jul. 11, 2011 (JP) 2011-152672

(51) Int. Cl. H01L 29/788

(52) U.S. Cl. 257/321; 257/E29.3

(57) ABSTRACT

In general, according to one embodiment, a semiconductor memory device includes active areas extending in a first direction, tunnel films provided on the active areas, floating gate electrodes provided on the tunnel films, an interelectrode insulating film provided on the floating gate electrodes and extending in a second direction, a control gate electrode provided on the interelectrode insulating film and extending in the second direction, a lower insulating portion provided between the active areas, between the tunnel films, and between the floating gate electrodes adjacent in the second direction, and an upper insulating portion provided between the lower insulating portion and the interelectrode insulating film. The lower insulating portion includes a void. Relative dielectric constant of the upper insulating portion is higher than that of the lower insulating portion. Relative dielectric constant of the interelectrode insulating film is higher than that of the upper insulating portion.

### CROSS-REFERENCE TO RELATED APPLICATIONS

This application is based upon and claims the benefit of priority from the prior Japanese Patent Application No. 2011-152672, filed on Jul. 11, 2011; the entire contents of which are incorporated herein by reference.

### FIELD

Embodiments described herein relate generally to a semiconductor memory device.

### BACKGROUND

Conventionally, NAND flash memories have been developed as nonvolatile semiconductor memory devices. In a NAND flash memory, STI (shallow trench isolation) extending in one direction is formed in an upper portion of a silicon substrate. This STI divides the upper portion of the silicon substrate into a plurality of active areas. A tunnel film is provided on each active area. A floating gate electrode is provided on the tunnel film. An interelectrode insulating film is provided so as to cover a plurality of floating gate electrodes provided on different active areas. A control gate electrode is provided on the interelectrode insulating film. By controlling the potential of the control gate electrode, charge is injected and extracted between the active area and the floating gate electrode via the tunnel film to store information. However, as the integration density of NAND flash memories becomes higher, the distance between the floating gate electrodes is reduced. This makes it difficult to suppress the interference between the floating gate electrodes.

### BRIEF DESCRIPTION OF THE DRAWINGS

FIG. 1 is a sectional view illustrating a semiconductor memory device according to a first embodiment;

FIG. 2A is a sectional view illustrating a semiconductor memory device according to a first comparative example, and FIG. 2B illustrates a simulation result for electric flux lines;

FIG. 3 is a sectional view illustrating a semiconductor memory device according to a second comparative example;

FIG. 4 is a sectional view illustrating a semiconductor memory device according to a second embodiment;

FIG. 5 is a sectional view illustrating a semiconductor memory device according to a third embodiment;

FIG. 6 is a sectional view illustrating a semiconductor memory device according to a fourth embodiment;

FIGS. 7A to 7C and 8A to 8C are process sectional views illustrating a method for manufacturing a semiconductor memory device according to a fifth embodiment; and

FIG. 9 is a sectional view illustrating a semiconductor memory device according to a sixth embodiment.

### DETAILED DESCRIPTION

In general, according to one embodiment, a semiconductor memory device includes a semiconductor substrate with an upper portion divided into a plurality of active areas extending in a first direction, tunnel films provided on the active areas, floating gate electrodes provided on the tunnel films, an interelectrode insulating film provided on the floating gate electrodes and extending in a second direction crossing the first direction, a control gate electrode provided on the interelectrode insulating film and extending in the second direction, a lower insulating portion provided between the active areas, between the tunnel films, and between the floating gate electrodes adjacent in the second direction, and an upper insulating portion provided between the lower insulating portion and the interelectrode insulating film, with an upper surface located higher than upper surfaces of the floating gate electrodes. The lower insulating portion includes a void. Relative dielectric constant of the upper insulating portion is higher than relative dielectric constant of the lower insulating portion. Relative dielectric constant of the interelectrode insulating film is higher than the relative dielectric constant of the upper insulating portion.

Embodiments of the invention will now be described with reference to the drawings.

First, a first embodiment is described.

The semiconductor memory device according to the embodiment is a NAND flash memory.

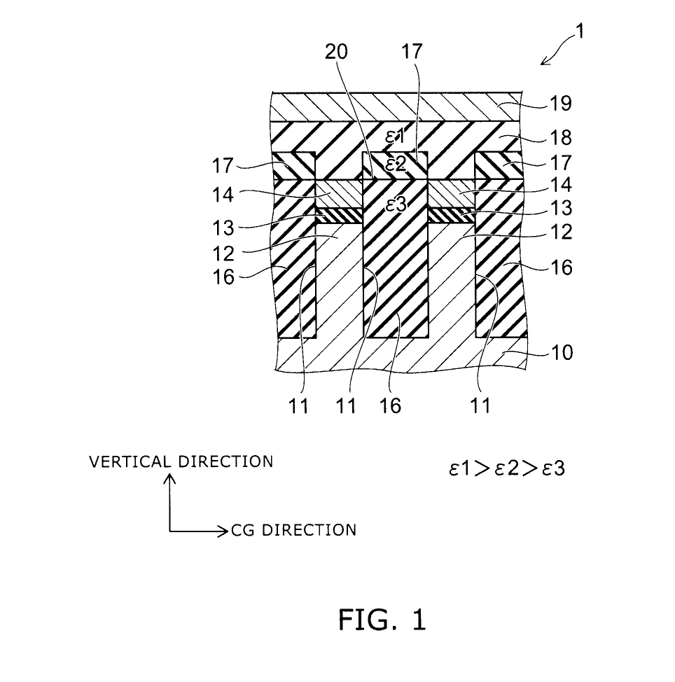

FIG. 1 is a sectional view illustrating the semiconductor memory device according to the embodiment.

As shown in FIG. 1, the semiconductor memory device 1 according to the embodiment includes a silicon substrate 10. In an upper portion of the silicon substrate 10, a trench 11 extending in one direction (hereinafter referred to as “AA direction”) is formed. This trench 11 divides the upper portion of the silicon substrate 10 into a plurality of active areas 12. Each active area 12 extends along the AA direction.

A tunnel film 13 is provided on each active area 12. The lower surface of the tunnel film 13 is in contact with the upper surface of the active area 12. The tunnel film 13 is a film passing a tunnel current upon application of a prescribed voltage within the driving voltage range of the semiconductor memory device 1. For instance, the tunnel film 13 is formed from an insulative material such as silicon oxide. Here, the tunnel film 13 may be a multilayer film, such as ONO film.

A floating gate electrode 14 is provided on the tunnel film 13. The lower surface of the floating gate electrode 14 is in contact with the upper surface of the tunnel film 13. The floating gate electrode 14 is located immediately above the active area 12, and divided in the AA direction. Thus, in the semiconductor memory device 1, as viewed from above, a plurality of floating gate electrodes 14 are arranged in a matrix configuration along the AA direction and the direction orthogonal thereto (hereinafter referred to as “CG direction”). The floating gate electrode 14 is formed from a conductive material, e.g., impurity-doped polysilicon, metal such as titanium or tungsten, or metal nitride such as titanium nitride or tungsten nitride. The floating gate electrode 14 is surrounded with an insulating material, and hence placed in an electrically floating state.

A lower insulating portion 16 is provided in the trench, i.e., between the adjacent active areas 12, between the tunnel films 13 provided immediately above these active areas 12, and between the floating gate electrodes 14 provided immediately above these active areas 12. The lower insulating portion 16 is insulative as a whole. However, the lower insulating portion 16 is not necessarily made of a single member. In at least part of the lower insulating portion 16, a void (not shown) is formed. The void is a cavity including a gas such as air, and is referred to as air gap.

An upper insulating portion 17 is provided immediately above the lower insulating portion 16. The upper insulating portion 17 is formed from e.g. a single insulative material, such as silicon oxide, silicon nitride, or silicate. The interface 20 between the lower insulating portion 16 and the upper insulating portion 17 is located at the same height as the upper surface of the floating gate electrode 14. Hence, the upper surface of the upper insulating portion 17 is located higher than the upper surface of the floating gate electrode 14.

An interelectrode insulating film 18 is provided above the floating gate electrode 14 and the upper insulating portion 17 so as to cover them. Each interelectrode insulating film 18 extends in the CG direction so as to connect the regions immediately above the floating gate electrodes 14, and is in contact with the floating gate electrode 14 and the upper insulating portion 17. Hence, the upper insulating portion 17 is provided between the lower insulating portion 16 and the interelectrode insulating film 18. The interelectrode insulating film 18 is formed from a high dielectric constant material, e.g., metal oxide such as lanthanum oxide, lanthanum aluminum oxide, lanthanum hafnium oxide, hafnium oxide, hafnium aluminum oxide, or aluminum oxide. In addition to these metal oxides, it is also possible to use silicate containing silicon, such as lanthanum silicate, lanthanum aluminum silicate, lanthanum hafnium silicate, hafnium silicate, hafnium aluminum silicate, or aluminum silicate. Here, if silicate is used for both the interelectrode insulating film 18 and the upper insulating portion 17, the concentration of metal element in the interelectrode insulating film 18 is made higher than the concentration of metal element in the upper insulating portion 17.

A control gate electrode 19 is provided immediately above each interelectrode insulating film 18. The control gate electrode 19 is shaped like a stripe and extends in the CG direction. The control gate electrode 19 is in contact with the interelectrode insulating film 18. The control gate electrode 19 is formed form e.g. metal.

An interlayer insulating film (not shown) is provided on the control gate electrode 19. This interlayer insulating film covers a plurality of control gate electrodes 19 arranged along the AA direction. However, the void (not shown) is located between the floating gate electrodes 14 adjacent in the AA direction. On the interlayer insulating film, source lines (not shown) extending in the CG direction and bit lines (not shown) extending in the AA direction are provided.

The relative dielectric constant ε2 of the upper insulating portion 17 is higher than the relative dielectric constant ε3 of the lower insulating portion 16. The relative dielectric constant εl of the interelectrode insulating film 18 is higher than the relative dielectric constant ε2 of the upper insulating portion 17. That is, ε1>ε2>ε3. As described above, the interelectrode insulating film 18 is formed from e.g. lanthanum oxide, lanthanum aluminum oxide, lanthanum hafnium oxide, hafnium oxide, hafnium aluminum oxide, or aluminum oxide. The relative dielectric constant ε1 thereof is e.g. 12-40, such as approximately 30. The upper insulating portion 17 is formed from e.g. silicon oxide, silicon nitride, or silicate. The relative dielectric constant ε2 thereof is e.g. 3-11, such as 7. The lower insulating portion 16 includes a void, and the relative dielectric constant ε3 of the lower insulating portion 16 as a whole is e.g. 1-3. If the lower insulating portion 16 is entirely a void, the relative dielectric constant ε3 thereof is approximately 1.

Next, the operation and effect of the embodiment are described.

In the semiconductor memory device 1 according to the embodiment, the lower insulating portion 16 is provided between the floating gate electrodes 14 adjacent in the CG direction. A void (not shown) is provided in at least part of the lower insulating portion 16. Hence, the lower insulating portion 16 as a whole has a low relative dielectric constant ε3. Thus, the interference between the floating gate electrodes 14 adjacent in the CG direction can be suppressed.

In the semiconductor memory device 1, the interelectrode insulating film 18 is provided between the floating gate electrode 14 and the control gate electrode 19. The interelectrode insulating film 18 is formed from a high dielectric constant material such as lanthanum oxide, and hence has a high relative dielectric constant ε1. Thus, high coupling ratio (CR) can be achieved between the control gate electrode 19 and the floating gate electrode 14.

The upper insulating portion 17 is provided between the floating gate electrode 14 and the control gate electrode 19, immediately above the region between the floating gate electrodes 14 adjacent in the CG direction. The relative dielectric constant ε2 of the upper insulating portion 17 is higher than the relative dielectric constant ε3 of the lower insulating portion 16, and lower than the relative dielectric constant ε1 of the interelectrode insulating film 18. Thus, while ensuring a sufficient coupling ratio between the control gate electrode 19 and the floating gate electrode 14, the interference between the floating gate electrodes 14 can be suppressed. As a result, even if the packing density of the semiconductor memory device 1 is increased, injection and extraction of charge in the floating gate electrode 14 by the control gate electrode 19 can be efficiently performed. Thus, write operation and erase operation for data can be reliably performed. Furthermore, the charge injected into a floating gate electrode 14 can be prevented from leaking with the operation of the adjacent floating gate electrode 14. Thus, the written data can be reliably retained. Hence, even if the packing density of the semiconductor memory device 1 is increased, the reliability of operation can be ensured.

That is, as the difference between the relative dielectric constants ε1, ε2, ξ3 becomes larger, the advantageous effect becomes higher. In the embodiment, the lower insulating portion 16 includes a void. Hence, advantageously, the relative dielectric constant ε3 can be made close to 1.

Furthermore, in the semiconductor memory device 1, a void is located also between the floating gate electrodes 14 adjacent in the AA direction. Hence, the interference can be prevented also between these floating gate electrodes 14.

Next, a first comparative example is described.

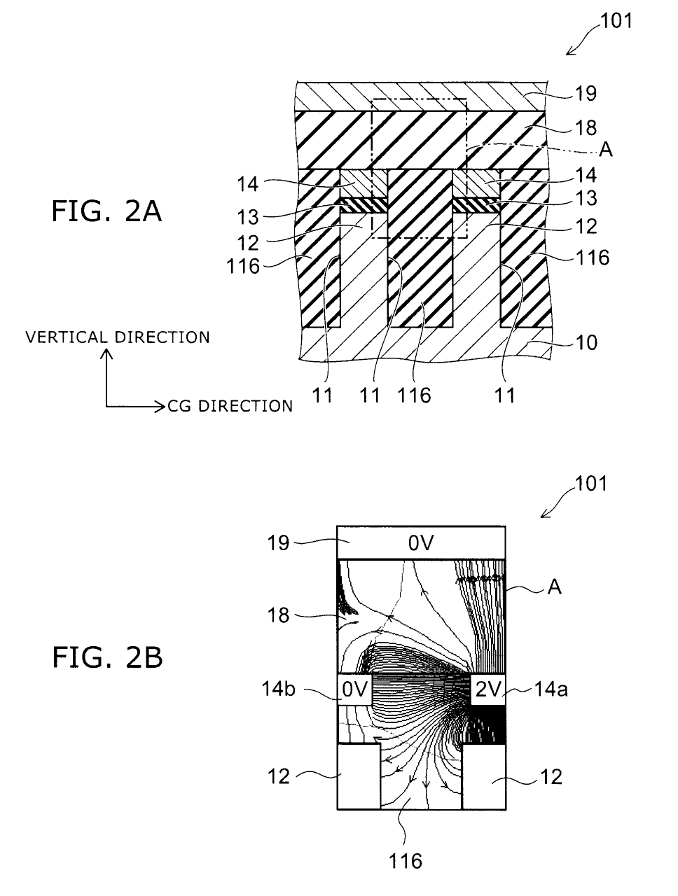

FIG. 2A is a sectional view illustrating a semiconductor memory device according to the comparative example. FIG. 2B illustrates a simulation result for electric flux lines.

As shown in FIG. 2A, the semiconductor memory device 101 according to the comparative example is different from the semiconductor memory device 1 (see FIG. 1) according to the above first embodiment in that the lower insulating portion 116 is composed of STI made of silicon oxide. Furthermore, the upper insulating portion 17 is not provided. The position where the upper insulating portion 17 is provided in the first embodiment is also occupied by the interelectrode insulating film 18 made of a high dielectric constant material.

FIG. 2B shows region A shown in FIG. 2A. The potential of the control gate electrode 19 is set to 0 V, and the potential of a floating gate electrode 14a is set to 2 V. As viewed from this floating gate electrode 14a, a floating gate electrode 14b located adjacently in the CG direction is set to a potential of 0 V. In this case, a simulation result for electric flux lines generated between these electrodes is shown in FIG. 2B.

As shown in FIG. 2B, in the semiconductor memory device 101, many electric flux lines are generated between the control gate electrode 19 and the floating gate electrode 14a. Thus, a favorable coupling ratio is achieved. However, also between the floating gate electrode 14a and the floating gate electrode 14b, many electric flux lines are generated via the lower insulating portion 116 and the interelectrode insulating film 18, causing interference. Thus, the semiconductor memory device 101 according to the comparative example has low charge retention characteristic in the floating gate electrode 14. In particular, if the packing density of the semiconductor memory device 101 is increased, this problem becomes conspicuous.

Next, a second comparative example is described.

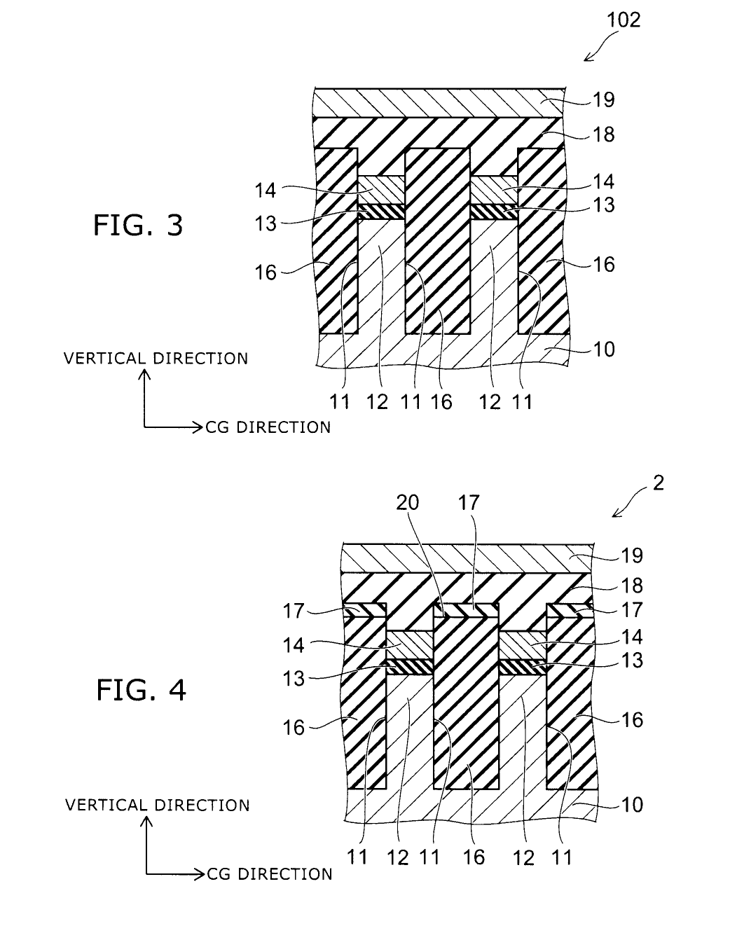

FIG. 3 is a sectional view illustrating a semiconductor memory device according to the comparative example.

As shown in FIG. 3, the semiconductor memory device 102 according to the comparative example is different from the semiconductor memory device 1 (see FIG. 1) according to the above first embodiment in that the upper insulating portion 17 (see FIG. 1) is not provided. The position where the upper insulating portion 17 is provided in the first embodiment is also occupied by the lower insulating portion 16.

In the comparative example, the lower insulating portion 16 having low relative dielectric constant is provided. Thus, the interference between the floating gate electrodes 14 adjacent in the CG direction can be suppressed. However, the lower insulating portion 16 is interposed also in part of the space between the control gate electrode 19 and the floating gate electrode 14. This results in low coupling ratio between the control gate electrode 19 and the floating gate electrode 14. Thus, the semiconductor memory device 102 according to the comparative example has low write/erase characteristic for the floating gate electrode 14. In particular, if the packing density of the semiconductor memory device 102 is increased, this problem becomes conspicuous.

Next, a second embodiment is described.

FIG. 4 is a sectional view illustrating a semiconductor memory device according to the embodiment.

As shown in FIG. 4, in the semiconductor memory device 2 according to the embodiment, the interface 20 between the lower insulating portion 16 and the upper insulating portion 17 is located higher than the upper surface of the floating gate electrode 14.

Thus, compared with the semiconductor memory device 1 (see FIG. 1) according to the above first embodiment, the interference between the floating gate electrodes 14 can be suppressed more effectively. However, the coupling ratio between the control gate electrode 19 and the floating gate electrode 14 is higher in the semiconductor memory device 1. That is, the position of the interface 20 between the lower insulating portion 16 and the upper insulating portion 17 can be selected to adjust the balance between the effect of suppressing the interference between the floating gate electrodes 14 and the effect of increasing the coupling ratio between the control gate electrode 19 and the floating gate electrode 14. The configuration and the operation and effect of the embodiment other than the foregoing are similar to those of the above first embodiment.

Next, a third embodiment is described.

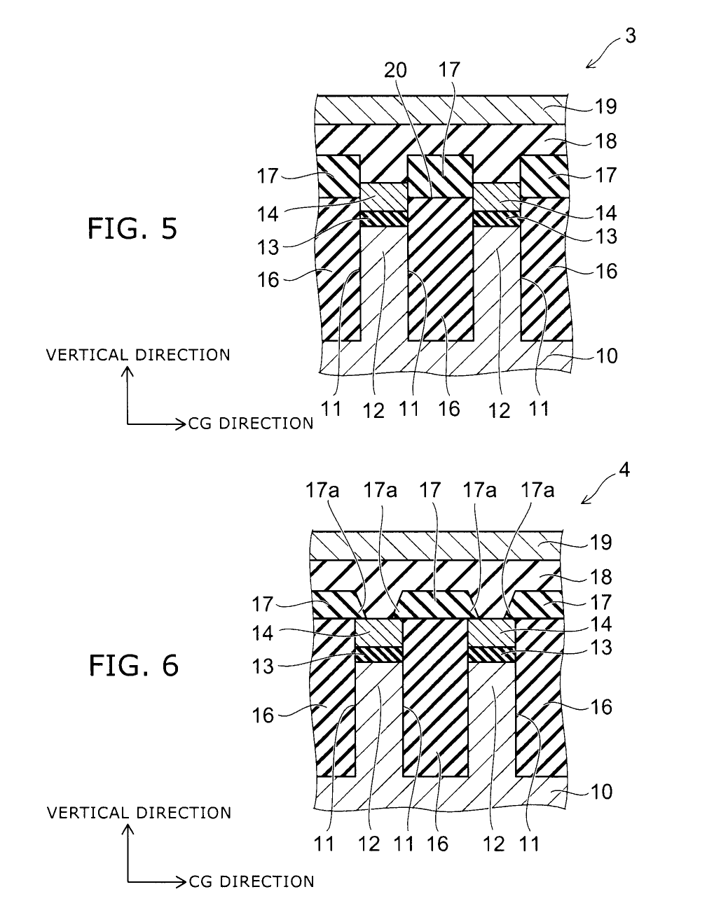

FIG. 5 is a sectional view illustrating a semiconductor memory device according to the embodiment.

As shown in FIG. 5, in the semiconductor memory device 3 according to the embodiment, the interface 20 between the lower insulating portion 16 and the upper insulating portion 17 is located lower than the upper surface of the floating gate electrode 14.

Thus, compared with the semiconductor memory device 1 (see FIG. 1) according to the above first embodiment, the coupling ratio between the control gate electrode 19 and the floating gate electrode 14 can be further increased. However, the effect of suppressing the interference between the floating gate electrodes 14 is higher in the semiconductor memory device 1. That is, as in the above second embodiment, the position of the interface 20 can be selected to control the balance of characteristics. The configuration and the operation and effect of the embodiment other than the foregoing are similar to those of the above first embodiment.

Next, a fourth embodiment is described.

FIG. 6 is a sectional view illustrating a semiconductor memory device according to the embodiment.

As shown in FIG. 6, the semiconductor memory device 4 according to the embodiment is different from the semiconductor memory device 1 (see FIG. 1) according to the above first embodiment in that part of the upper insulating portion 17 overhangs immediately above both CG-direction end portions of the floating gate electrode 14. Thus, in the upper surface of the floating gate electrode 14, both CG-direction end portions are covered with the overhanging portion 17a of the upper insulating portion 17. On the other hand, in the upper surface of the floating gate electrode 14, the CG-direction central portion is not covered with the upper insulating portion 17, but is in contact with the interelectrode insulating film 18.

In the embodiment, the corner portion formed by the upper surface of the floating gate electrode 14 and its side surface facing the CG direction is covered with the upper insulating portion 17. The overhanging portion 17a of the upper insulating portion 17 is located at the position where electric flux lines concentrate in FIG. 2B. Hence, compared with the semiconductor memory device 1 (see FIG. 1) according to the above first embodiment, the interference between the adjacent floating gate electrodes 14 can be suppressed more effectively. The configuration and the operation and effect of the embodiment other than the foregoing are similar to those of the above first embodiment.

Next, a fifth embodiment is described.

The embodiment is an example method for manufacturing the semiconductor memory device according to the above fourth embodiment.

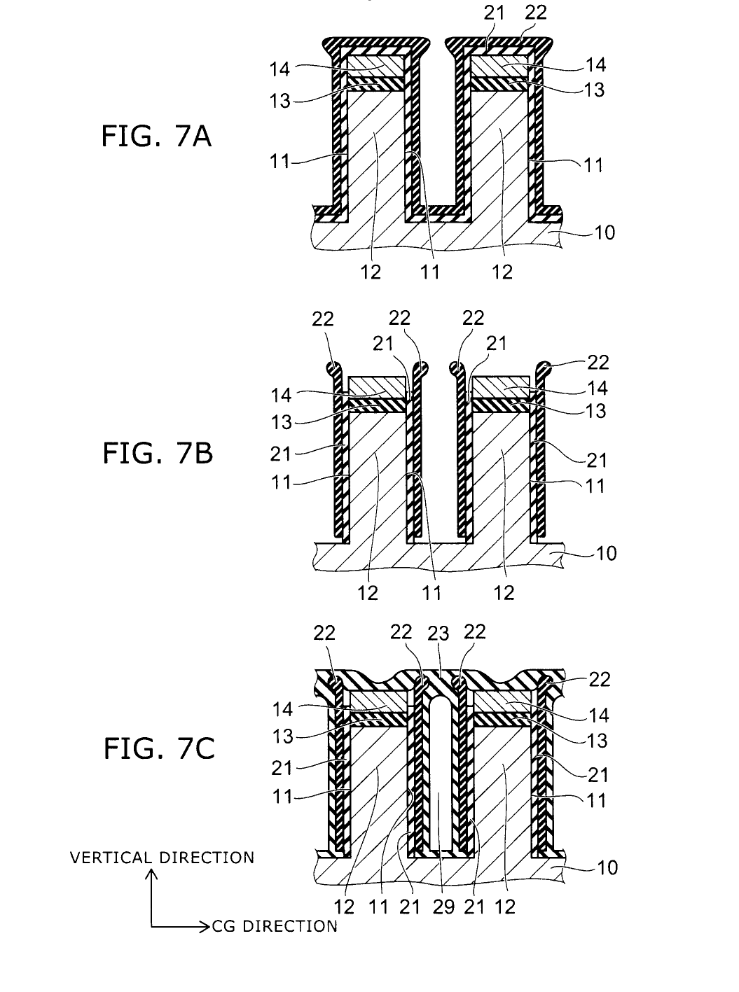

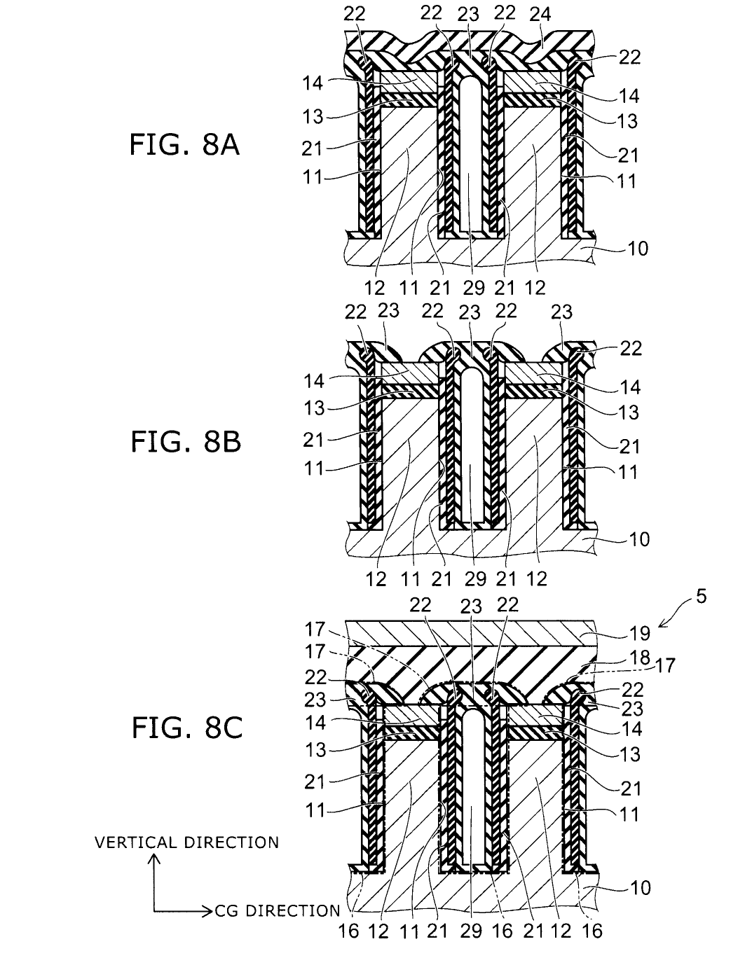

FIGS. 7A to 7C and 8A to 8C are process sectional views illustrating the method for manufacturing a semiconductor memory device according to the embodiment.

First, as shown in FIG. 7A, a silicon substrate 10 made of single crystal silicon is prepared. Next, on the entire surface of the silicon substrate 10, a tunnel film 13 made of e.g. silicon oxide is formed. Next, on the entire surface of the tunnel film 13, for instance, impurity-doped polysilicon is deposited to form a floating gate electrode 14. At this stage, the tunnel film 13 and the floating gate electrode 14 are not divided, but are made of a continuous film.

Next, in the structure in which the tunnel film 13 and the floating gate electrode 14 are stacked on the silicon substrate 10, a plurality of trenches 11 extending in the AA direction are formed. Thus, the floating gate electrode 14 and the tunnel film 13 are divided into a plurality of striped portions extending in the AA direction. At the same time, the upper portion of the silicon substrate 10 is divided into a plurality of active areas 12 extending in the AA direction.

Next, a silicon oxide film 21 is formed on the entire surface. The silicon oxide film 21 is formed on the inner surface of the trench 11 and on the upper surface of the floating gate electrode 14. Next, a silicon nitride film 22 is deposited on the entire surface. The silicon nitride film 22 is formed relatively thick on the upper surface of the floating gate electrode 14 and on the side surface of the upper end portion of the trench 11, and relatively thin on the inner surface of the portion of the trench 11 other than the upper end portion. Thus, in the upper end portion of the trench 11, the silicon nitride film 22 is projected like eaves in the direction of coming close to each other. As a result, the opening width of the trench 11 in the upper end portion is made narrower than the width of the portion of the trench 11 other than the upper end portion.

Next, as shown in FIG. 7B, RIE (reactive ion etching) is performed to etch back the silicon nitride film 22. Thus, in the silicon nitride film 22, the portion deposited on the upper surface of the floating gate electrode 14 and the portion deposited on the bottom surface of the trench 11 are removed. As a result, on the upper surface of the floating gate electrode 14 and on the bottom surface of the trench 11, the silicon oxide film 21 is exposed. On the other hand, the portion of the silicon nitride film 22 deposited on the side surface of the trench 11 is left.

Next, wet etching with hydrofluoric acid, for instance, is performed to remove the exposed portion of the silicon oxide film 21, i.e., the portion covering the upper portion of the floating gate electrode 14, and the portion deposited on the bottom surface of the trench 11. Thus, the upper portion of the floating gate electrode 14 is exposed, and the silicon substrate 10 is exposed at the bottom surface of the trench 11. At this time, the upper end portion of the remaining silicon nitride film 22, i.e., the portion projected like eaves immediately above the trench 11, is located higher than the upper surface of the floating gate electrode 14.

Next, as shown in FIG. 7C, by a method with relatively high coverage such as the ALD (atomic layer deposition) method, silicon oxide is deposited on the entire surface to form a silicon oxide film 23. The silicon oxide film 23 is formed on the inner surface of the trench 11 and on the upper surface of the floating gate electrode 14. At the same time, the silicon oxide film 23 covers the silicon nitride film 22 projected like eaves in the upper end portion of the trench 11. Then, before the silicon oxide film 23 completely fills the inside of the trench 11, the portions of the silicon oxide film 23 covering the silicon nitride films 22 opposed to each other immediately above the trench 11 are brought into contact with each other to occlude the upper end portion of the trench 11. As a result, a void 29 is formed in the trench 11.

At this time, the upper end portion of the silicon nitride film 22 is located higher than the upper surface of the floating gate electrode 14. Hence, in the upper surface of the silicon oxide film 23, the region located immediately above the trench 11 is located higher than the region located immediately above the floating gate electrode 14. This forms protrusions and depressions in the upper surface of the silicon oxide film 23.

Next, as shown in FIG. 8A, by a method with relatively low coverage such as the CVD (chemical vapor deposition) method, silicon oxide is deposited on the entire surface to form a silicon oxide film 24. At this time, the upper end portion of the trench 11 is occluded with the silicon oxide film 23. Hence, the silicon oxide film 24 does not proceed into the trench 11. Furthermore, in the upper surface of the silicon oxide film 24, protrusions and depressions reflecting the shape of the silicon oxide film 23 are formed. That is, in the upper surface of the silicon oxide film 24, a protrusion occurs in the region immediately above the trench 11, and a depression occurs in the region immediately above the floating gate electrode 14.

Next, as shown in FIG. 8B, RIE is performed to etch back the silicon oxide films 24 and 23. At this time, the upper surface of the silicon oxide films 24 and 23 is set back while keeping the protrusions and depressions before starting RIE. As a result, immediately above the trench 11 and immediately above both CG-direction end portions of the floating gate electrode 14 where a protrusion was present before starting RIE, the silicon oxide film 23 is left. On the other hand, immediately above the CG-direction central portion of the floating gate electrode 14 where a depression was present before starting RIE, the silicon oxide film 23 is removed, and the floating gate electrode 14 is exposed. Here, the silicon oxide film 24 is almost entirely removed.

Next, as shown in FIG. 8C, lanthanum oxide, for instance, is deposited to form an interelectrode insulating film 18. The interelectrode insulating film 18 covers the remaining portion of the silicon oxide film 23, and is brought into contact with the upper surface of the CG-direction central portion of the floating gate electrode 14. Next, a metal, for instance, is deposited to form a control gate electrode 19. Next, by a lithography method, a resist mask (not shown) is formed and used as a mask to perform RIE. Thus, the control gate electrode 19, the interelectrode insulating film 18, the silicon oxide film 23, the silicon nitride film 22, and the floating gate electrode 14 are selectively removed and divided into striped portions extending in the CG direction. Next, an interlayer insulating film (not shown) is formed on the entire surface, and source lines (not shown) and bit lines (not shown) are formed. Thus, a semiconductor memory device 5 according to the embodiment is manufactured.

In the semiconductor memory device 5, the structure formed in the trench 11, i.e., the structure composed of the silicon oxide film 21, the portion of the silicon nitride film 22 located in the trench 11, the portion of the silicon oxide film 23 located in the trench 11, and the void 29, constitutes a lower insulating portion 16. Furthermore, the portion of the silicon nitride film 22 located above the floating gate electrode 14 and the portion of the silicon oxide film 23 located above the floating gate electrode 14 constitute an upper insulating portion 17. The upper insulating portion 17 is formed from silicon oxide and silicon nitride. The lower insulating portion 16 includes the void 29 besides silicon oxide and silicon nitride. Hence, the relative dielectric constant ε2 of the overall upper insulating portion 17 is higher than the relative dielectric constant ε3 of the overall lower insulating portion 16. Furthermore, the interelectrode insulating film 18 is formed from lanthanum oxide. Hence, the relative dielectric constant ε1 of the interelectrode insulating film 18 is higher than the relative dielectric constant ε2 of the upper insulating portion 17. The operation and effect of the embodiment are similar to those of the above fourth embodiment.

Next, a sixth embodiment is described.

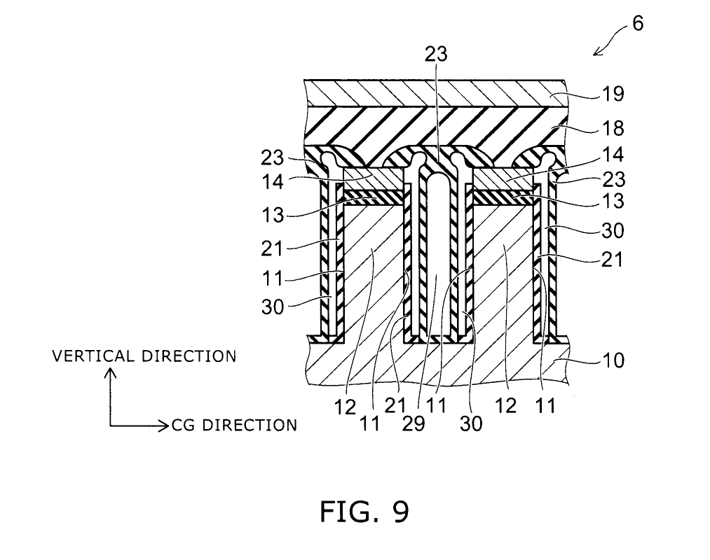

FIG. 9 is a sectional view illustrating a semiconductor memory device according to the embodiment.

As shown in FIG. 9, in the embodiment, in the step shown in FIG. 8C, the floating gate electrode 14, the interelectrode insulating film 18, and the control gate electrode 19 are selectively removed and divided into striped portions extending in the CG direction. Then, wet etching is performed to remove the silicon nitride film 22 (see FIG. 8C). Thus, the portion which was occupied by the silicon nitride film 22 constitutes a void 30. Subsequently, an interlayer insulating film (not shown), source lines (not shown), and bit lines (not shown) are formed. Thus, a semiconductor memory device 6 is manufactured.

In the embodiment, the silicon nitride film 22 (see FIG. 8C) is replaced by the void 30. Hence, compared with the semiconductor memory device 5 (see FIG. 8C) according to the above fifth embodiment, the relative dielectric constant of the lower insulating portion 16 and the upper insulating portion 17 is lower. Thus, the interference between the floating gate electrodes 14 can be suppressed more effectively. The configuration, the manufacturing method, and the operation and effect of the embodiment other than the foregoing are similar to those of the above fifth embodiment.

The embodiments described above can realize a semiconductor memory device capable of suppressing the interference between the floating gate electrodes while ensuring coupling between the control gate electrode and the floating gate electrode.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

Additionally, the embodiments described above can be combined mutually.

What is claimed is:

1. A semiconductor memory device comprising:
a semiconductor substrate with an upper portion divided into a plurality of active areas extending in a first direction;
tunnel films provided on the active areas;
floating gate electrodes provided on the tunnel films;
an interelectrode insulating film provided on the floating gate electrodes and extending in a second direction crossing the first direction;
a control gate electrode provided on the interelectrode insulating film and extending in the second direction;
a lower insulating portion provided between the active areas, between the tunnel films, and between the floating gate electrodes adjacent in the second direction; and
an upper insulating portion provided between the lower insulating portion and the interelectrode insulating film, with an upper surface located higher than upper surfaces of the floating gate electrodes,
the lower insulating portion including a void, and
relative dielectric constant of the upper insulating portion being higher than relative dielectric constant of the lower insulating portion, and relative dielectric constant of the interelectrode insulating film being higher than the relative dielectric constant of the upper insulating portion.

2. The device according to claim 1, wherein interface between the lower insulating portion and the upper insulating portion is located higher than the upper surfaces of the floating gate electrodes.

3. The device according to claim 1, wherein interface between the lower insulating portion and the upper insulating portion is located at same height as the upper surface of one of the floating gate electrodes.

4. The device according to claim 1, wherein interface between the lower insulating portion and the upper insulating portion is located lower than the upper surfaces of the floating gate electrodes.

5. The device according to claim 1, wherein part of the upper insulating portion overhangs immediately above the floating gate electrode.

6. The device according to claim 1, wherein
both end portions in the second direction of the upper surface of each of the floating gate electrodes are covered with the upper insulating portion, and
a central portion in the second direction of the upper surface of each of the floating gate electrodes is in contact with the interelectrode insulating film.

7. The device according to claim 1, wherein the interelectrode insulating film is made of metal oxide or silicate.

8. The device according to claim 1, wherein the upper insulating portion and the interelectrode insulating film are both made of silicate, and concentration of metal element in the interelectrode insulating film is higher than concentration of metal element in the upper insulating portion.

9. The device according to claim 1, wherein
the upper insulating portion includes one or more materials selected from the group consisting of silicon oxide, silicon nitride, and silicate, and
the interelectrode insulating film includes one or more materials selected from the group consisting of lanthanum oxide, lanthanum aluminum oxide, lanthanum hafnium oxide, hafnium oxide, hafnium aluminum oxide, aluminum oxide, lanthanum silicate, lanthanum aluminum silicate, lanthanum hafnium silicate, hafnium silicate, hafnium aluminum silicate, and aluminum silicate.

10. The device according to claim 1, wherein
the relative dielectric constant of the interelectrode insulating film is 12 to 40,
the relative dielectric constant of the upper insulating portion is 3 to 11, and
the relative dielectric constant of the lower insulating portion is 1 to 3.
